(19) United States
(12) Patent Application Publication
(10) Pub. No.: US 2008/0032210 A1
(43) Pub. Date: Feb. 7, 2008

(54) METHOD FOR FABRICATING MASK AND DEVICE ISOLATION FILM

(76) Inventor: Jae-Young Choi, Seoul (KR)

Correspondence Address: SHERR & NOURSE, PLLC, 620 HERNDON PARKWAY, SUITE 200, HERNDON, VA, 20170, US

(21) Appl. No.: 11/833,055

(22) Filed: Aug. 2, 2007

(30) Foreign Application Priority Data
Aug. 3, 2006 (KR) 10-2006-0073478

(51) Int. Cl. G03F 1/00; G06F 17/50

(52) U.S. Cl. 430/5; 716/20

(57) ABSTRACT

Embodiments relate to a method for fabricating a mask used in a photolithography process. According to embodiments, a Design dimensions of DI model considering a line width of a photoresist after Photo Engraving Process (PEP) are corrected to be used. Among the design dimensions, a design dimension for a distance between patterns forming a mask and design dimension for each region included in each of the patterns may be differently corrected.

The present application claims priority under 35 U.S.C. 119 and 35 U.S.C. 365 to Korean Patent Application No. 10-2006-0073478 (filed on Aug. 3, 2006), which is hereby incorporated by reference in its entirety.

### BACKGROUND

Photolithography related processes may be significant in a semiconductor fabrication process. This may be because a photolithography process is an important aspect regarding how highly integrated a device may be and the degree of precision provided in a fabrication process.

As devices get more highly integrated, a pattern size should necessarily be reduced. In order to resolve such a small pattern, a fabrication process may need to be delicate.

Resolution Enhancement Technology (RET), a technology for resolution improvement and fidelity, has been developed because photolithography equipment may not be able to keep up with a pattern becoming smaller. Among this technology, Optical Proximity Correction (OPC) may be in use and OPC based on a simulation model may be in great use.

Among OPC related technologies, an OPC based on a model may be used in the foundry business. This may be because the OPC can be easily applied to various client databases or layouts unlike an OPC based on rules.

FIG. 1 is a diagram illustrating a related art mask pattern.

Critical Dimensions (CDs) of the related art mask pattern are to consider a CD of an after-exposure photoresist rather than a target CD of a layer intended for etching with a predetermined photoresist as an etching mask.

Accordingly, a structure such as a device isolation film which may have a great influence on a degree of integration of a semiconductor device has a problem that after etch, a trench may not be formed with a CD of a desired size.

In other words, there is a problem caused by considering a CD of an after-exposure photoresist without targeting a CD after a final etch process in designing a mask pattern.

### SUMMARY

Embodiments relate to a method for designing a region, which is a target of a mask pattern, considering an after-etch CD and forming a device isolation film using a mask.

Embodiments relate to a method for fabricating a mask, and more particularly, to a method for fabricating a mask allowing a device isolation film to have more accurate Critical Dimension (CD) and a method for forming a device isolation film using the mask.

According to embodiments, there may be provided a method for fabricating a mask used in a photolithography process, wherein design dimensions of DI model considering a line width of a photoresist after Photo Engraving Process (PEP) may be corrected to be used, and wherein, among the design dimensions, a design dimension for a distance between patterns forming a mask and design dimension for each region included in each of the patterns may be differently corrected.

According to embodiments, a method for forming a device isolation film may include forming sequentially an oxide film, a nitride film, and a Tetra Ethyl Ortho Silicate (TEOS) film on a silicon substrate, forming a photoresist having a predetermined pattern on the TEOS film, etching part of the TEOS film, the nitride film, the oxide film, and the silicon substrate using the photoresist as an etching mask, and after etching of the part of the silicon substrate, performing an etching process for forming a trench in the silicon substrate with the photoresist as an etching mask.

### DRAWINGS

FIG. 1 is a diagram illustrating a related art mask pattern.

FIGS. 2 to 5 are process cross-sectional diagrams illustrating a method for forming a device isolation film according to embodiments.

FIGS. 6 and 7 are graphs of distribution of CD versus pitch of mask pattern.

FIG. 8 illustrates a design of a mask fabricated according to embodiments.

FIG. 9 illustrates a pattern of a mask fabricated according to embodiments.

FIGS. 10 and 11 are Scanning Electron Microscope (SEM) photographs of an active region after a device isolation film may be formed using a mask fabricated in accordance with embodiments.

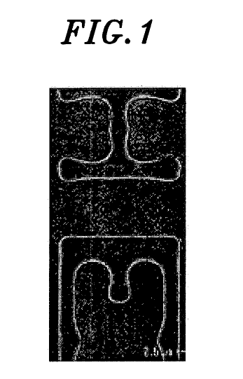

### DETAILED DESCRIPTION

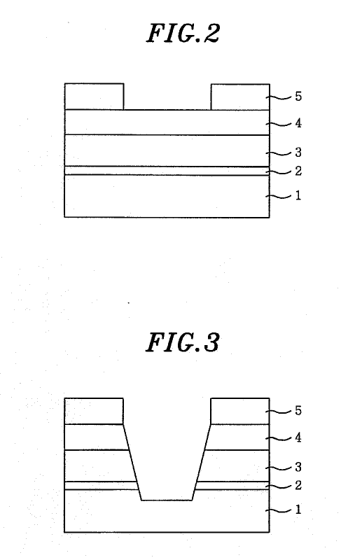

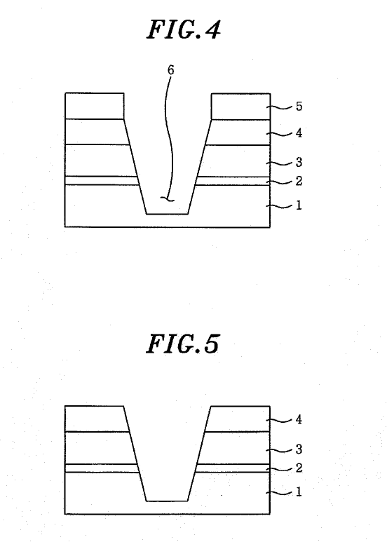

Referring to FIG. 2, oxide film 2, nitride film 3, and Tetra Ethyl Ortho Silicate (TEOS) film 4 may be sequentially deposited on silicon substrate 1.

Photoresist 5 may be formed to have a predetermined pattern on TEOS film 4. In embodiments, after Photo Engraving Process (PEP), photoresist 5 may have a predetermined pattern as shown in FIG. 2.

Referring to FIG. 3, TEOS film 4, nitride film 3, and oxide film 2 may be sequentially etched using photoresist 5 as an etching mask. In embodiments, even a predetermined portion of silicon substrate 1 can be etched together.

In embodiments, silicon substrate 1 may be etched to a predetermined depth in a secondary etching process for forming a device isolation film.

In other words, the device isolation film may be formed using photoresist 5 as an etching mask in first and second etching processes. In the first etching process, oxide film 2, nitride film 3, and TEOS film 4 formed on silicon substrate 1 may be etched and an upper part of silicon substrate 1 may be partially etched. In the second etching process, an insulation material may be buried within silicon substrate 1 and may be etched to form an active region.

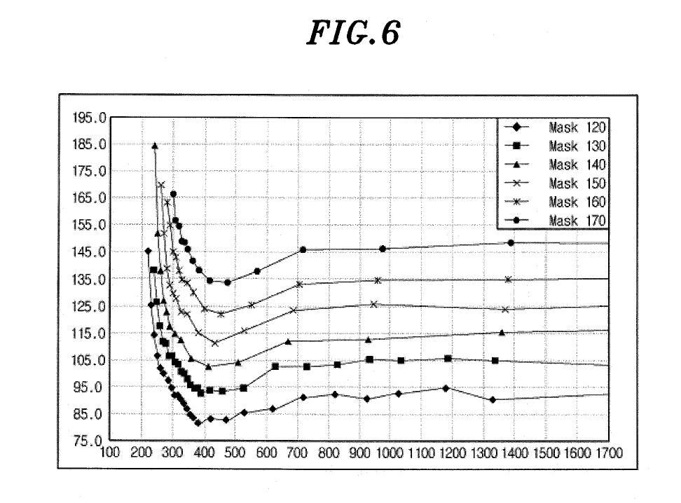

Referring to FIG. 5, photoresist 5 may be removed. Trench 6, which may be provided within silicon substrate 1, may be filled with an insulation material.

The following description is based on experiments implemented to fabricate a pattern of a mask considering an after-etch CD.

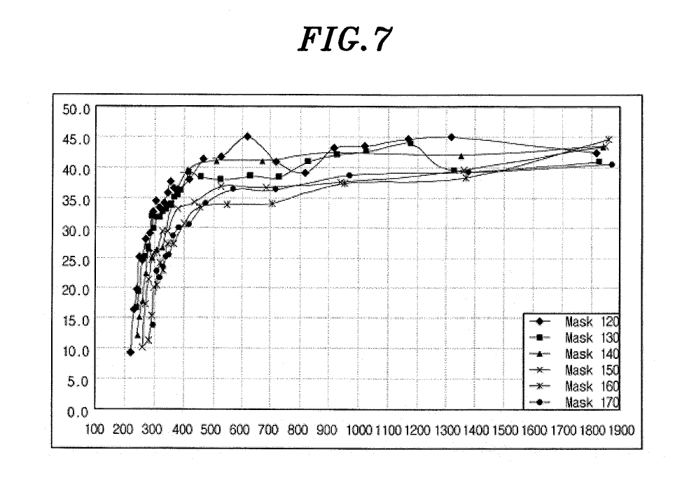

FIGS. 6 and 7 are graphs of distribution of CD versus pitch of mask pattern. In FIG. 6, the horizontal axis represents a pitch (nm) of a mask pattern, and the vertical axis represents a CD (nm) of an after-PEP photoresist. In FIG. 7, the horizontal axis represents a pitch (nm) of a mask pattern, and the vertical axis represents a difference (nm) between a CD of an after-PEP photoresist and a CD of an after-etch layer.

FIG. 6 is a graph of a distribution of a CD of an after-PEP photoresist shown as a pitch of a mask pattern (a distance between patterns) varies.

Referring to FIG. 6, it may be appreciated that when a mask has a size of about 120 nm to 170 nm, a CD of an after-PEP photoresist, which may vary depending on a pattern having a pitch of a diversity of sizes, may vary as the pitch increases. In embodiments, in photolithography process, a difference in an actual etched portion may occur depending on a distance between patterns that light cannot pass through by the proximity effect of light.

Referring to FIG. 6, it may be appreciated that a CD may decrease and may again increase at a semi-dense portion (e.g., a portion with a pitch of about 200 nm to 600 nm). A CD may be almost the same as that of an Iso-line (a portion with a pitch of about 1500 nm or more) when a pitch is within a range of about 700 nm or more.

FIG. 7 is a graph illustrating a difference between a CD of an after-PEP photoresist and a CD of an after-etch layer depending on a mask pattern having a pitch of a diversity of sizes.

FIG. 7 illustrates a difference between a CD of a photoresist and a CD of an after-etch layer as a pitch of a mask pattern varies. FIG. 7 illustrates that the mask pattern may be etched with more accuracy as the CD difference (a so-called CD bias) between the photoresist and the after-etch layer is smaller. In FIG. 7, Y-axis denotes the CD difference between the photoresist and the after-etch layer.

Referring to FIG. 7, a variation of bias depending on a size of a mask may not be so great. In other words, masks having a diversity of sizes such as mask 120 to mask 170 may have almost the same CD bias distribution.

In embodiments, a dense line (a portion with a pitch of about 600 nm or less) may have a bias of about 10 nm. In embodiments, an Iso-line (a portion with a pitch of about 1500 nm or more) may have a bias of about 42 nm.

Therefore, an OPC model simply modeled using only data on a CD of an after-PEP photoresist without considering these biases may not be able to satisfy a process target in photolithography process. As a result, it may cause inconsistency with a target in an etching process for forming a pattern in a wafer. This may make it very difficult to perform accurate OPC.

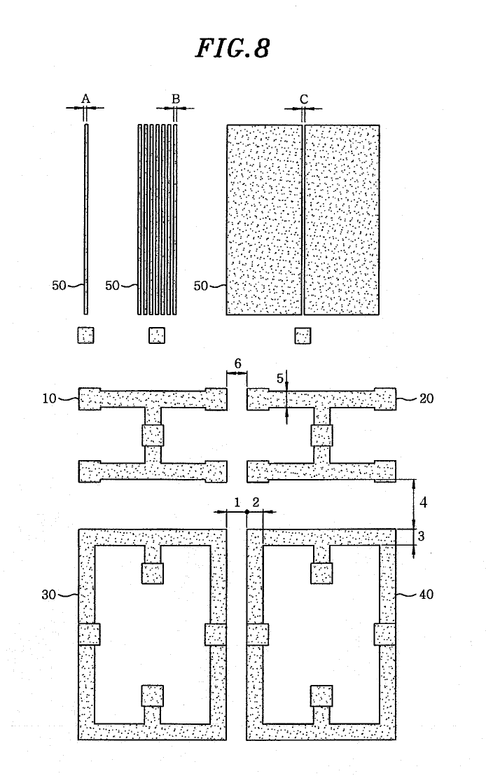

FIG. 8 illustrates a design of a mask fabricated according to embodiments.

Experimental data for fabricating, by the mask design of FIG. 8, a mask considering a target CD after etching will be provided below.

FIG. 8 illustrates a variety of formats of patterns. The respective patterns may be formed to be at a predetermined interval. The shown mask pattern shows PSC mark 50 and an SRAM.

The SRAM may be comprised of first pattern 10, second pattern 20, third pattern 30, and fourth pattern 40 each formed to be at a predetermined distance. Respective patterns 10, 20, 30, and 40 may be of a shape of a series of regions which light may not pass through.

In embodiments, first pattern 10 and second pattern 20 may be of an H shape. Third pattern 30 and fourth pattern 40 may be of a rectangular shape.

Reference numeral 6 denotes a distance between first pattern 10 and second pattern 20. Reference numeral 4 denotes a distance between second pattern 20 and fourth pattern 40. Reference numeral 1 denotes a distance between third pattern 30 and fourth pattern 40.

Reference numeral 5 denotes a thickness of any one of regions of second pattern 20 which light may not pass through. Reference numerals 2 and 3 denote regions of fourth pattern 40 which light may not pass through.

In other words, the mask patterns shown in FIG. 8 can be classified into the first to fourth patterns. The respective patterns may be formed to be at a predetermined distance. Here, a distance between the patterns and a thickness of a region constituting each pattern can be designed in a desirable size.

Referring to experimental data below, a description of a design for the mask pattern may be apparent. However, Tables 1 to 3 below show many pieces of experiment data and various target CDs for respective regions constituting the mask pattern. Thus, each Table will be divided and described.

TABLE 1

| Division | Target (nm) | DI model (nm) | FI model (nm) |
|---|---|---|---|
| A | 105 | 132 | 133 |
| B | 105 | 125 | 127 |
| C | 147 | 137 | 133 |
| 1 | 151 | 130 | 131 |
| 2 | 115 | 146 | 142 |
| 3 | 166 | 194 | 187 |
| 4 | 345 | 303 | 317 |
| 5 | 115 | 154 | 138 |
| 6 | 152 | 126 | 128 |

Table 1 shows a target CD of an after-etch layer, data on a design by general DI model according to the related art art, and data on a design by FI model according to embodiments, based on the fabricating the mask pattern of FIG. 8.

Embodiments use general DI model targeting a CD of an after-PEP photoresist, and suggests FI model to design a CD of an after-etch layer with more accuracy.

In embodiments, a design for a gap between patterns and a design for a region constituting each pattern may be applied differently.

Referring to FIG. 8, distance 6 between first pattern 10 and second pattern 20, distance 4 between second pattern 20 and fourth pattern 40, and distance 1 between third pattern 30 and fourth pattern 40 may be designed to be greater than a target CD by a predetermined length. For example, when a target CD of distance 6 between first pattern 10 and second pattern 20 is equal to 152 nm, a mask may be designed to have a size of 128 nm greater by a predetermined value than a size of 126 nm of DI model considering a CD of an after-PEP photoresist.

The distance between the patterns may be designed greater than a DI model value considering a CD of an after-PEP photoresist. In such a method, distances 1, 4, and 6 between the patterns may be designed.

A region constituting each pattern may be designed smaller than a DI model value considering a CD of an after-PEP photoresist. Describing a design for a partial region 5 of second pattern 20 for example, when a target CD is equal to 115 nm, region 5 may be designed to have a size of 154 nm in DI model but may be designed to have a size of 138 nm smaller by a predetermined value than the 154 nm in FI model in accordance with embodiments.

As described above, FI model considering a CD of an after-etch layer may use a value of DI model, and may have a value greater or smaller within 10% of a design dimension of the DI model.

An after-PEP CD by DI model and FI model will be described with reference to Table 2. An after-etch CD will be described with reference to Table 3. However, experiments were performed with different target CDs.

TABLE 2

| Division | Target (nm) | DI model (nm) | FI model (nm) |
|---|---|---|---|
| A | 105 | 106 | 108 |
| B | 115 | 117 | 117 |
| C | 134 | 133 | 134 |
| 1 | 141 | 142 | 139 |
| 2 | 125 | 124 | 128 |
| 3 | 176 | 171 | 171 |
| 4 | 335 | 328 | 341 |
| 5 | 125 | 125 | 127 |
| 6 | 142 | 135 | 127 |

Table 2 shows data on a target CD of an after-PEP photoresist pattern, data on a CD of a photoresist observed from general DI model, and data on a CD of a photoresist observed from FI model according to embodiments.

FI model is OPC considering a CD of an after-etch layer. Therefore, it may be appreciated that a CD of an after-PEP photoresist pattern may have a great difference with an actual target value as shown in Table 2.

DI model is OPC considering a CD of an after-PEP photoresist. Therefore, an actual CD of a photoresist may be closer to a target CD.

For example, in embodiments when a target is equal to 142 nm, a CD may be equal to 135 nm in DI model but may be equal to 127 nm in FI model.

However, much importance to an operation of a semiconductor device actually is that how much accurately an active region may be fabricated using a device isolation film formed after etching. Therefore, it may be appreciated that embodiments may be more effective in Table 3 below.

TABLE 3

| Division | Target (nm) | DI model (nm) | FI model (nm) |
|---|---|---|---|
| A | 145 | 143 | 146 |
| B | 135 | 134 | 135 |
| C | 116 | 115 | 116 |
| 1 | 117 | 119 | 116 |
| 2 | 150 | 147 | 152 |
| 3 | 196 | 205 | 200 |
| 4 | 315 | 298 | 313 |
| 5 | 145 | 159 | 154 |
| 6 | 101 | 105 | 100 |

Table 3 shows data on a target CD, data on a CD of an after-etch layer etched using a mask designed by DI model for the target CD, and data on a CD of an after-etch layer etched using a mask designed by FI model for the target CD.

As a result, it may be appreciated that a CD of layer actually observed in FI model for a target CD may be more accurate. For example, in embodiments, for distance 6, when a target CD is equal to 101 nm, a CD may be equal to 105 nm in DI model but may be equal to 100 nm in FI model.

It may be desirable that a mask pattern be fabricated such that a distance between respective mask patterns is greater than that of DI model by a predetermined dimension and a region constituting each pattern is smaller than that of DI model by a predetermined dimension.

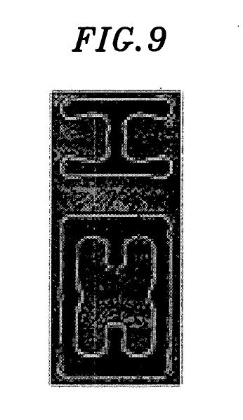

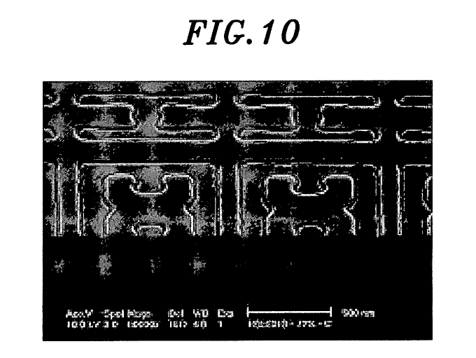

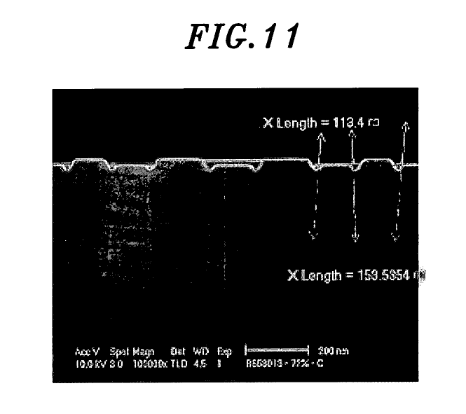

FIG. 9 illustrates a pattern of a mask fabricated in accordance with embodiments. FIGS. 10 and 11 are Scanning Electron Microscope (SEM) photographs of an active region after a device isolation film may be formed using a mask fabricated in accordance with embodiments.

The mask of FIG. 9 is a result of using a DI model value considering a CD of an after-PEP photoresist and applying a design for a distance between patterns of a mask and a design for a region constituting a pattern differently, according to embodiments.

In FIGS. 10 and 11, an active region may be formed with more accuracy where a device isolation film is formed using a mask in accordance with embodiments.

A method for fabricating a mask and a method for forming a device isolation film using the mask may be advantageous in the improvement of device integration because a target CD may be realized with more accuracy.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method for fabricating a photolithography mask, comprising:
correcting and using design dimensions of a Developed Image (DI) model considering a line width of a photoresist after a Photo Engraving Process (PEP); and
independently correcting a design dimension for a distance between patterns forming a mask and a design dimension for each region included in each of the patterns.

2. The method of claim 1, wherein the distance between the patterns is corrected to be greater by a predetermined value than a corresponding dimension of the distance of the DI model.

3. The method of claim 1, wherein the region constituting each pattern is corrected to be smaller than that of the DI model by a second predetermined dimension.

4. The method of claim 1, wherein the correction of the design dimension for the distance between patterns forming the mask is different from the correction for the design dimension for each region included in each of the patterns.

5. The method of claim 1, wherein the distance between respective mask patterns is corrected to be greater than that of the DI model by a first predetermined dimension and the region constituting each pattern is corrected to be smaller than that of the DI model by a second predetermined dimension.

6. The method of claim 5, further comprising:
sequentially forming an oxide film, a nitride film, and a Tetra Ethyl Ortho Silicate (TEOS) film over a silicon substrate;
forming a photoresist over the TEOS film using the photolithography mask;
etching at least a portion of the TEOS film, the nitride film, the oxide film, and the silicon substrate using the photoresist as an etching mask; and
forming a trench in the silicon substrate by performing an etching process with the photoresist as an etching mask.

7. A method for forming a device isolation film, comprising:
forming sequentially an oxide film, a nitride film, and a Tetra Ethyl Ortho Silicate (TEOS) film over a silicon substrate;
forming a photoresist having a predetermined pattern over the TEOS film;
etching at least a portion of the TEOS film, the nitride film, the oxide film, and the silicon substrate using the photoresist as an etching mask; and
forming a trench in the silicon substrate by performing an etching process with the photoresist as an etching mask.

8. The method of claim 7, wherein the predetermined pattern of the photoresist is formed by correcting and using design dimensions of a DI model considering a line width of a photoresist after a Photo Engraving Process (PEP), and by using a mask in which a design dimension for a distance between patterns forming a mask and a design dimension for each region included in each of the patterns are independently corrected.

9. The method of claim 8, wherein design dimension for the distance between patterns forming the mask are corrected than the design dimension for each region included in each of the patterns.

10. The method of claim 8, wherein the distance between the patterns is corrected to be greater by a predetermined value than a corresponding dimension of the distance of the DI model.

11. The method of claim 8, wherein the region constituting each pattern is corrected to be smaller than that of the DI model by a second predetermined dimension.

12. The method of claim 8, wherein the distance between patterns forming the mask is greater than that of the DI model by a predetermined amount and the region included in each of the patterns is smaller than that of DI model by a predetermined dimension.

13. A mask used in a photolithography process, comprising:
a plurality of mask patterns having a first design dimension representing a distance between each of the plurality of patterns and a second design dimension representing each region included in each of the patterns,
wherein the mask is formed by correcting and using first and second design dimensions of a DI model considering a line width of a photoresist after a Photo Engraving Process (PEP), and
wherein among the first and second design dimensions, the first design dimension for the distance between patterns forming the mask and the second design dimension for each region included in each of the patterns are corrected independently of each other.

14. The mask of claim 13, wherein the distance between the patterns is corrected to be greater by a predetermined value than a corresponding distance of the DI model.

15. The method of claim 13, wherein the region constituting each pattern is corrected to be smaller than that of the DI model by a second predetermined dimension.

16. The mask of claim 13, wherein an amount of correction of the first design dimension is different than an amount of correction of the second design dimension.

17. The mask of claim 13, wherein the distance between respective patterns forming the mask is greater than that of the DI model by a predetermined dimension and the region included in each of the patterns is smaller than that of the DI model by a predetermined dimension.
